(19) United States
(12) Patent Application Publication
(10) Pub. No.: US 2007/0229174 A1
(43) Pub. Date: Oct. 4, 2007

(54) CALIBRATION LOOP, FILTER CIRCUIT AND RELATED METHOD CAPABLE OF AUTOMATICALLY ADJUSTING CENTER FREQUENCY OF A FILTER

(76) Inventors: Kwo-Wei Chang, Hsinchu County (TW); Chun-Yi Li, Taipei City (TW); Wen-Jan Lee, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 11/562,991

(22) Filed: Nov. 23, 2006

(30) Foreign Application Priority Data
Mar. 14, 2006 (TW) 095108642

(51) Int. Cl. H03L 7/00

(52) U.S. Cl. 331/16

(57) ABSTRACT

A calibration loop includes an oscillator, an integrator, an amplitude comparator, and a working voltage adjuster. The oscillator is used for generating a reference clock signal. The integrator is coupled to the oscillator for generating an output amplitude according to the reference clock signal and a working voltage. The first input end of the amplitude comparator is coupled to the integrator and the second input end of the amplitude comparator is coupled to the oscillator. The amplitude comparator is used for comparing the output amplitude of the integrator with an amplitude of the reference clock signal of the oscillator and outputting a comparison result. The input end of the working voltage adjuster is coupled to the amplitude comparator, and the output end of the working voltage adjuster is coupled to the integrator. The working voltage adjuster is used for tuning the input working voltage according to the comparison result.

### BACKGROUND OF THE INVENTION

1. Field of the Invention

The present invention relates to a filter circuit capable of adjusting a center frequency of a filter, and more particularly, to a filter circuit that utilizes an integrator to adjust the center frequency of the filter.

2. Description of the Prior Art

The tendency of chip integration continues to head towards more logic components and smaller areas. At present, a chip designer lessens external components for lowering cost and reducing the areas of the circuit as far as possible. Hence, this becomes an essential technology to integrate external components into internal chip, such as integrating a filter into a chip.

A filter is a commonly seen component in communication transmission fields. Generally speaking, discrete time filters control bandwidth accurately but are applicable to narrow bandwidth. More often than not, high-frequency circuits adopt continuous time filters where a transconductance-c filter is the first choice due to its power consumption. The drawbacks of a transconductance-c filter are that it varies in production processing and has different characteristic parameters. These characteristic parameters vary with environment, such as temperature variation and bias effect. The value of a transconductance, a resistor, and a capacitor affect the characteristic of the circuit directly such as the center frequency of the filter, the gain of the amplifier, etc and further affect the stability and performance of the integration circuit.

In the prior art, mathematical operations are applied to adjust the center frequency of a filter. In general, adopting a filter which is similar to the structure of the adjusted filter as the adjustment criteria. For example, duplicating a slave filter from a phase lock loop to adjust the adjusted filter, where the voltage controlled oscillator (VCO) of the phase lock loop is derived from part of the master filter. The drawbacks of the method are that it wastes large area and power consumption. Besides, calibration speed of the phase lock loop is slow and spends too much time.

### SUMMARY OF THE INVENTION

The claimed invention provides a calibration loop, a filter circuit and related method capable of adjusting a center frequency of a filter. The filter circuit includes the calibration loop and a filter. The calibration loop includes an oscillator, an integrator, an amplitude comparator, and a working voltage adjuster. The oscillator is used for generating a reference clock signal. The integrator is coupled to the oscillator for generating an output amplitude according to the reference clock signal and a working voltage. The first input end of the amplitude comparator is coupled to the integrator and the second input end of the amplitude comparator is coupled to the oscillator. The amplitude comparator is used for comparing the output amplitude of the integrator with the amplitude of the reference clock signal of the oscillator and outputting a comparison result. The input end of the working voltage adjuster is coupled to the amplitude comparator and the output end of the working voltage adjuster is coupled to the integrator. The working voltage adjuster is used for tuning the input working voltage according to the comparison result.

The claimed invention further provides a method for adjusting a center frequency of a filter. The method includes generating a reference clock signal and generating an output amplitude according to the reference clock signal and a working voltage. The output amplitude is compared with an amplitude of the reference clock signal to obtain a comparison result. The working voltage is then adjusted according to the comparison result and the center frequency of the filter is adjusted according to the adjusted working voltage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a filter circuit capable of adjusting center frequency of a filter according to the present invention.

FIG. 2 is a circuit diagram illustrating the filter of the filter circuit in FIG. 1.

FIG. 3 is a diagram illustrating the gyrator of the filter in FIG. 2.

FIG. 4 is a diagram illustrating the integrator of the filter circuit in FIG. 1.

### DETAILED DESCRIPTION

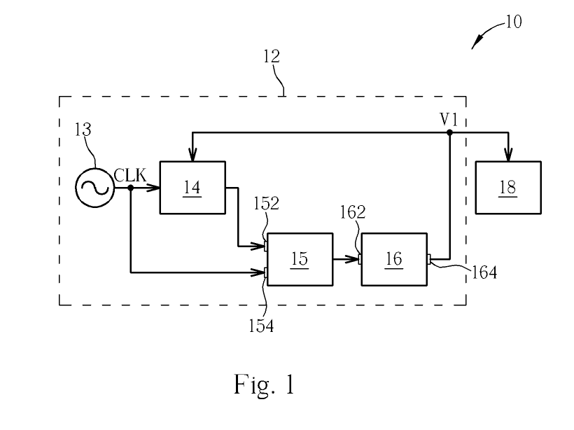

Please refer to FIG. 1. FIG. 1 is a diagram of a filter circuit 10 capable of adjusting center frequency of a filter according to the present invention. Filter circuit 10 includes a calibration loop 12 and a filter 18. The calibration loop 12 includes an oscillator 13, an integrator 14, an amplitude comparator 15, and a working voltage adjuster 16. The oscillator 13 is a quartz oscillator for generating a reference clock signal CLK with a frequency fc. In one embodiment, the reference clock signal CLK is a sine-wave signal. The quartz oscillator is suited to be the standard of the amplitude comparator due to the stable frequency characteristic itself. The integrator 14 is coupled to the oscillator 13 for generating an output amplitude according to a working voltage V1. The integrator 14 includes a unity gain frequency fu that corresponds to the output amplitude. The amplitude comparator 15 includes a first input end 152 coupled to the integrator 14 for receiving the output amplitude and a second input end 154 coupled to the oscillator 13. The amplitude comparator 15 is used for comparing the output amplitude of the integrator 14 with the amplitude of the reference clock signal CLK and outputting a comparison result. The working voltage adjuster 16 has an input end 162 coupled to the amplitude comparator 15, and an output end 164 coupled to the integrator 14 and the filter 18. The working voltage adjuster 16 is used for tuning the working voltage V1 of the integrator 14 and the filter 18 according to the comparison result. The oscillator 13, the integrator 14, the amplitude comparator 15, the working voltage adjuster 16, and the filter 18 are integrated on a same chip.

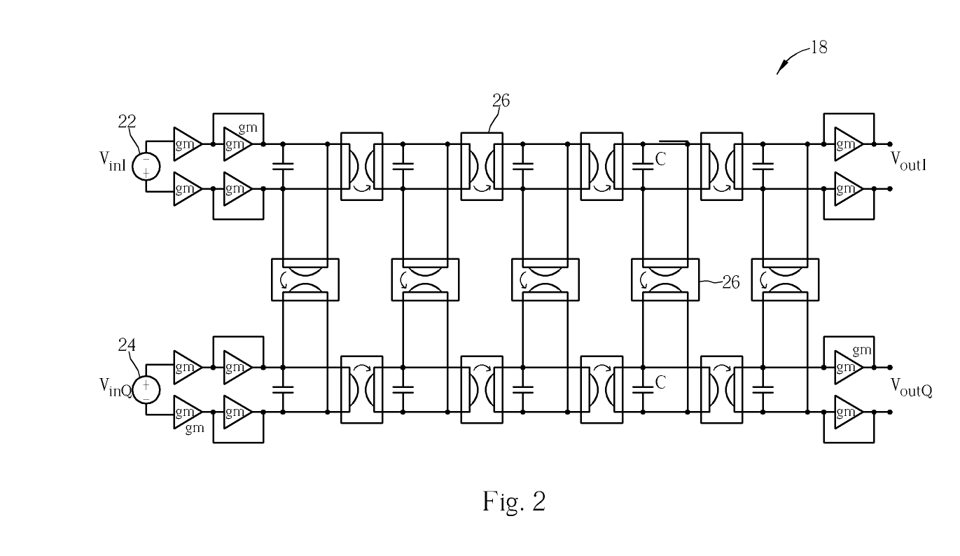

Please refer to FIG. 2 that is a circuit diagram illustrating the filter 18 of the filter circuit 10 of FIG. 1. The filter 18 is a transconductance-c filter that includes a plurality of gyrators 26, a plurality of capacitors C, and a plurality of transconductors gm. The filter 18 includes two voltage sources 22 and 24 for providing two input voltages VinI and VinQ. A first end of the voltage source 22 is coupled to one transconductor gm and a second end of the voltage source 22 is coupled to another transconductor gm. A first end of the voltage source 24 is coupled to one transconductor gm and a second end of the voltage source 24 is coupled to another transconductor gm. The input voltages VinI and VinQ pass through the plurality of coupled gyrators 26 and capacitors C, the filter 18 outputs two output voltages VoutI and VoutQ as accomplished filtering. The filter 18 includes a center frequency fc that is generated according to the working voltage V1. The center frequency fc is decided by the transconductor gm and the capacitor C using an equation fc=transconductance/(2*pi*C). Due to the value of the transconductor gm varying with the working voltage V1 (as shown in FIG. 1), the higher the working voltage V1, the higher the value of the transconductor gm. The center frequency fc of the filter 18 is decided by the ratio of the value of transconductance gm to the value of the capacitor C. Adjusting the working voltage V1 of the filter 18 can adjust transconductance and further adjusts the center frequency fc.

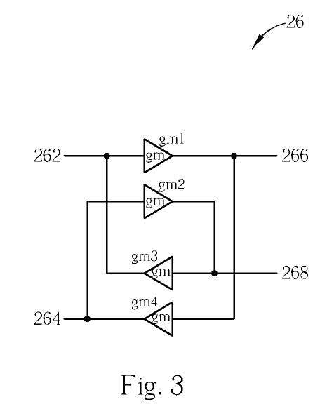

Please refer to FIG. 3 that is a diagram illustrating the gyrator 26 of the filter 18 of FIG. 2. The gyrator 26 includes four transconductors gm, a first input end 262, a second input end 264, a first output end 266, and a second output end 268. An input end of a first transconductor gm1 is coupled to an output end of a third transconductor gm3 and is the first input end 262 of the gyrator 26. An input end of a second transconductor gm2 is coupled to an output end of a fourth transconductor gm4 and is the second input end 264 of the gyrator 26. An output end of the first transconductor gm1 is coupled to an input end of a fourth transconductor gm4 and is the first output end 266 of the gyrator 26. An output end of the second transconductor gm2 is coupled to an input end of the third transconductor gm3 and is the second output end 268 of the gyrator 26. The value of the transconductor gm and the value of the gyrator 26 are the same.

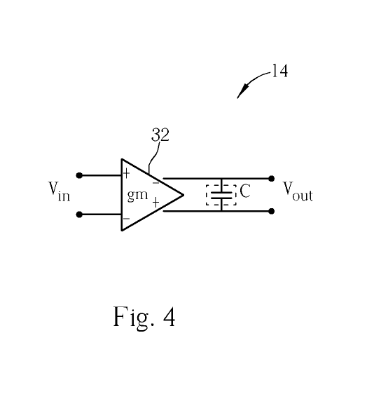

Please refer to FIG. 4 that is a diagram illustrating the integrator 14 of the filter circuit 10 of FIG. 1. The integrator 14 includes a differential transconductor 32 and a capacitor C. The integrator 14 includes an input voltage Vin and an output voltage Vout. The differential transconductor 32 is coupled to the oscillator 13 and the working voltage adjuster 16 (as shown in FIG. 1) for generating a driving signal according to the reference clock signal CLK and the working voltage V1. The capacitor C is coupled to the differential transconductor 32 for charging or discharging to generate the output amplitude according to the driving signal of the differential transconductor 32. The integrator 14 includes a unity gain frequency fu that is decided by the differential transconductor 32 and the capacitor C with an equation fu=transconductance/(2*pi*C). Therefore, the unity gain frequency fu of the integrator 14 is the same as the center frequency fc of the filter 18. The integrator 14 and the filter 18 adjust simultaneously due to the unity gain frequency fu of the integrator 14 corresponding with the center frequency fc of the filter 18. The gain of the integrator 14 is 1 when working at frequency fu, that is the amplitude of the input voltage Vin equals the amplitude of the output voltage Vout. The gain of the integrator 14 is greater than 1 when working at frequency higher than fu, meaning that the amplitude of the output voltage Vout is larger than the amplitude of the input voltage Vin. The gain of the integrator 14 is less than 1 when working at frequency less than fu, meaning that the amplitude of the output voltage Vout is less than the amplitude of the input voltage Vin. The unity gain frequency fu can be adjusted by this characteristic of the integrator 14.

Please keep on referring to FIG. 1. The oscillator 13 provides the reference clock signal CLK with a frequency fc as the standard. The amplitude comparator 15 is used for comparing the amplitude of the input signal with the output signal of the integrator 14. If the amplitude of the output signal of the integrator 14 is greater than the reference clock signal CLk, that means the frequency fu is greater than the frequency fc and lowering the working voltage V1 using the working voltage adjuster 16 to lower the frequency fu is appropriate. If the amplitude of the output signal of the integrator 14 is less than the reference clock signal CLk, that means the frequency fu is less than the frequency fc and raising the working voltage V1 using the working voltage adjuster 16 to raise the frequency fu is appropriate. After the continuous calibration of the calibration loop 12, the frequency fu equals the frequency fc finally. That is the unity gain frequency fu of the integrator 14 is the same as the center frequency fc of the filter 18.

The above-mentioned embodiments illustrate but do not limit the present invention. The filter 18 is not restricted to a transconductance-c filter only. The integrator 14 is not restricted to an integrator comprises transconductors and capacitors.

In conclusion, the present invention provides a calibration loop 12 and a filter circuit 10 capable of adjusting a center frequency of a filter. Adjusting the center frequency fc of the filter 18 by the integrator 14 comprising the same components reduces errors in the filter circuit. Moreover, the oscillator 13, the integrator 14, the amplitude comparator 15, the working voltage adjuster 16, and the filter 18 are integrated on a same chip to lessen external components. This lowers the cost and saves area on a circuit board. The present invention does not require a phase lock loop, saving more area and power consumption. Furthermore, adjusting the center frequency of the filter by a simple integrator is practical and economical.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A calibration loop capable of adjusting center frequency of a filter comprising:
an oscillator for generating a reference clock signal;
an integrator coupled to the oscillator for generating an output amplitude according to the reference clock signal and a working voltage;
an amplitude comparator including a first input end coupled to the integrator and a second input end coupled to the oscillator, the amplitude comparator used for comparing the output amplitude of the integrator with an amplitude of the reference clock signal of the oscillator and outputting a comparison result; and
a working voltage adjuster including an input end coupled to the amplitude comparator and an output end coupled to the integrator, the working voltage adjuster used for tuning the working voltage of the integrator according to the comparison result outputted from the amplitude comparator.

2. The calibration loop of claim 1 wherein the integrator includes a unity gain frequency that corresponds with the output amplitude.

3. The calibration loop of claim 2 wherein the unity gain frequency of the integrator corresponds with the center frequency of the filter.

4. The calibration loop of claim 1 wherein the oscillator, the integrator, the amplitude comparator, and the working voltage adjuster are integrated on a same chip.

5. The calibration loop of claim 1 wherein the oscillator is a quartz oscillator.

6. The calibration loop of claim 1 wherein the integrator comprises:
a transconductor coupled to the oscillator and the working voltage adjuster for generating a driving signal according to the reference clock signal and the working voltage; and
a capacitor coupled to the transconductor for charging and discharging to generate the output amplitude according to the driving signal outputted from the transconductor.

7. A filter circuit capable of adjusting center frequency of a filter comprising:
an oscillator for generating a reference clock signal;
an integrator coupled to the oscillator for generating an output amplitude according to the reference clock signal and a working voltage;
an amplitude comparator including a first input end coupled to the integrator and a second input end coupled to the oscillator, the amplitude comparator used for comparing the output amplitude of the integrator with an amplitude of the reference clock signal of the oscillator and outputting a comparison result;
a filter for generating a center frequency according to the working voltage; and
a working voltage adjuster including an input end coupled to the amplitude comparator and an output end coupled to the integrator, the working voltage adjuster used for tuning the working voltage of the integrator according to the comparison result outputted from the amplitude comparator.

8. The filter circuit of claim 7 wherein the integrator includes a unity gain frequency that corresponds with the output amplitude.

9. The filter circuit of claim 8 wherein the unity gain frequency of the integrator corresponds with the center frequency of the filter.

10. The filter circuit of claim 7 wherein the oscillator, the integrator, the amplitude comparator, the working voltage adjuster, and the filter are integrated on a same chip.

11. The filter circuit of claim 7 wherein the oscillator is a quartz oscillator.

12. The filter circuit of claim 7 wherein the filter is a transconductance-c filter.

13. The filter circuit of claim 7 wherein the filter comprises a plurality of transconductors and a plurality of capacitors.

14. The filter circuit of claim 7 wherein the integrator comprises:
a transconductor coupled to the oscillator and the working voltage adjuster for generating a driving signal according to the reference clock signal and the working voltage; and
a capacitor coupled to the transconductor for charging or discharging to generate the output amplitude according to the driving signal outputted from the transconductor.

15. A method for adjusting center frequency of a filter, the method comprising:
generating a reference clock signal;
generating an output amplitude according to the reference clock signal and a working voltage;
comparing the output amplitude with an amplitude of the reference clock signal and outputting a comparison result;
adjusting the working voltage according to the comparison result; and
adjusting the center frequency of the filter according to the adjusted working voltage.

16. The method of claim 15 wherein generating the output amplitude according to the reference clock signal and the working voltage further comprises:
generating a driving signal according to the reference clock signal and the working voltage; and
charging or discharging a capacitor to generate the output amplitude according to the driving signal.
